(19) United States
(12) Patent Application Publication
(10) Pub. No.: US 2008/0203471 A1
(43) Pub. Date: Aug. 28, 2008

(54) NITRIDE SEMICONDUCTOR DEVICE AND METHOD FOR PRODUCING NITRIDE SEMICONDUCTOR DEVICE

(75) Inventors: Hirotaka Otake, Kyoto (JP); Shin Egami, Kyoto (JP); Hiroaki Ohta, Kyoto (JP)

Correspondence Address: RABIN & Berdo, PC, 1101 14TH STREET, NW, SUITE 500, WASHINGTON, DC, 20005, US

(73) Assignee: ROHM CO., LTD., Kyoto (JP)

(21) Appl. No.: 12/036,575

(22) Filed: Feb. 25, 2008

(30) Foreign Application Priority Data
Feb. 26, 2007 (JP) JP-2007-045217

(51) Int. Cl. H01L 29/78; H01L 21/336

(52) U.S. Cl. 257/329; 438/269; 257/E29.089; 257/E29.262; 257/E21.399; 257/E21.41

(57) ABSTRACT

The nitride semiconductor device includes: a nitride semiconductor structure comprising an n-type first layer, a p-type second layer, and an n-type third layer, the nitride semiconductor structure comprising a mesa structure having a lateral surface which forms a wall surface extending from the first, second, to third layers; a gate insulating film formed on the wall surface of the mesa structure; a gate electrode formed as facing the wall surface in the second layer; a drain electrode electrically connected to the first layer; and a source electrode electrically connected to the third layer, the nitride semiconductor structure having a high dislocation region and a low dislocation region arranged along a direction parallel to a principal surface of lamination of the nitride semiconductor structure, a dislocation density of the low dislocation region being lower than that of the high dislocation region, the mesa structure being formed in the low dislocation region.

### TECHNICAL FIELD

The present invention relates to a nitride semiconductor device using a Group III nitride semiconductor and a manufacturing method thereof.

### DESCRIPTION OF RELATED ART

Conventionally, a power device using a silicon semiconductor is used for a power amplifier circuit, a power supply circuit, a motor drive circuit, or the like.

However, from theoretical limitations of the silicon semiconductor, high withstand voltage, low resistance, and high speed of the silicon device have nearly reached their limits, which leads to difficulties in satisfying market needs.

Therefore, consideration has been given to the development of a GaN device having characteristics such as high withstand voltage, high-temperature operation, a large current density, high-speed switching, low on-resistance, and the like. In particular, in view of ensuring the withstand voltage property, the development of a vertically structured GaN device has been advanced in which a source electrode and a drain electrode are arranged in a perpendicular direction (for example, see Satoshi OKUBO, “Mou Hikarudakejanai Kikinoshinkanourani GaN”, Jun. 5, 2006, Nikkei Electronics, p. 51-60).

The vertically structured GaN device is provided with: a conductive SiC substrate; a GaN thin film formed on the SiC substrate; an n-type GaN layer formed on the GaN thin film; and a p-type region formed near a surface of the n-type GaN layer, for example. The SiC substrate is formed with a drain electrode, the surface of the n-type GaN layer is formed with a source electrode, and the p-type region is formed with a gate electrode via a gate insulating film, respectively. Accordingly, the vertical structure is formed in which the source electrode and the drain electrode are arranged in a perpendicular direction. During operation of the device, a current is passed from the drain electrode via the SiC substrate, the GaN thin film, and the n-type GaN layer to the source electrode.

In manufacturing of the vertically structured GaN device, the GaN thin film is first formed on the SiC substrate. Subsequently, the GaN thin film is used as a nucleus, the n-type GaN layer is crystal-grown in a vertical direction (direction perpendicular to the SiC substrate). Thereafter, the p-type region is formed near the surface of the n-type GaN layer. The drain electrode is formed on the SiC substrate, the source electrode is formed on the surface of the n-type GaN layer, and the gate electrode is formed via the gate insulating film in the p-type region. Accordingly, the vertically structured GaN device is obtained.

### DISCLOSURE OF THE INVENTION

### Problems to be Solved

However, at steps of manufacturing the above-mentioned vertically structured GaN device, resulting from a mismatch between a lattice constant of the SiC substrate and that of the GaN thin film, a large number of dislocation defects (crystal defects) which penetrate in a perpendicular direction from the SiC substrate through the GaN thin film and the n-type GaN layer may possibly be generated. That is, a large number of dislocation defects may possibly be generated in a region in which a current is passed during operation of the GaN device. As a result, a leak current may be generated during operation of the GaN device to lower electrical characteristics of the device. Therefore, such a GaN device has a problem that it is not necessarily suitable for the power device.

Therefore, an object of the present invention is to provide a Group III nitride semiconductor device suitably applied to a power device, or the like, and a manufacturing method thereof.

### Solution to the Problems

A nitride semiconductor device of the present invention includes: a nitride semiconductor structure comprising an n-type first layer, a p-type second layer provided on the first layer, and an n-type third layer provided on the second layer, each layer of the nitride semiconductor structure being made of a Group III nitride semiconductor, the nitride semiconductor structure comprising a mesa structure having a lateral surface which forms a wall surface extending from the first, second, to third layers; a gate insulating film formed on the wall surface of the mesa structure such that the gate insulating film extends over the first, second, and third layers; a gate electrode formed as facing the wall surface in the second layer with the gate insulating film being sandwiched between the gate electrode and the wall surface; a drain electrode electrically connected to the first layer; and a source electrode electrically connected to the third layer in the mesa structure, the nitride semiconductor structure having a high dislocation region and a low dislocation region arranged along a direction parallel to a principal surface of lamination of the nitride semiconductor structure, a dislocation density of the low dislocation region being lower than that of the high dislocation region, the mesa structure being formed in the low dislocation region. The shape of the mesa structure used herein may be trapezoidal or rectangular in a cross section cutting a lateral surface of the mesa structure in a perpendicular direction.

According to this configuration, the nitride semiconductor structure is provided with a mesa structure having a lateral surface which forms a wall surface extending from the n-type first layer, the p-type second layer, to the n-type third layer. The wall surface of the mesa structure is formed with a gate insulating film such that the gate insulating film extends over the first, second, and third layers. The gate electrode is formed as facing the wall surface in the second layer with the gate insulating film being sandwiched between the gate electrode and the wall surface. The drain electrode is formed such that the drain electrode is electrically connected to the first layer, and the source electrode is further formed such that the source electrode is electrically connected to the third layer in the mesa structure. Accordingly, a vertical MIS (Metal Insulator Semiconductor) field effect transistor (hereinafter, this transistor is simply referred to as a “MISFET”) is configured.

An operation of the thus configured MISFET is described. A voltage is applied to the source electrode and the drain electrode such that the drain electrode is positive. At this time, a pn junction portion at an interface between the first and second layers is applied a reverse voltage, so that the source and drain are nonconductive. From this state, when a voltage of a predetermined voltage value (gate threshold voltage) or more which is positive with respect to the second layer is applied to the gate electrode, electrons are induced in a region (channel region) near a surface facing the gate electrode in the second layer to form an inversion layer (channel). Via the inversion layer, conduction is provided between the first and third layers in the mesa structure. Thus, the source and drain are conducted each other. In this way, when an appropriate voltage is applied to the gate electrode, the source and drain are conducted each other.

In the MISFET, the mesa structure, which is a region through which a current flows during the above-described operation, is formed in the low dislocation region out of the high dislocation region of which a dislocation density is high and the low dislocation region of which a dislocation density is lower than that of the high dislocation region, each of which region is formed in the nitride semiconductor structure. Therefore, generation of a leak current during operation of the MISFET can be reduced. As a result, lowering of the electrical characteristics of the MISFET can be suppressed, and thus, such a MISFET can realize an excellent power device.

Because the nitride semiconductor device is adapted as a basic structure for a vertical MISFET, a normally-off operation, i.e., an operation in which the source and drain are in an off state when no bias is applied to the gate electrode can be easily realized. As a result of integration, a large amount of current can flow easily, and thickening of the first layer can also secure high withstand voltage easily. Therefore, an effective power device can be provided. Of course, since the field effect transistor is configured with the Group III nitride semiconductor layer, characteristics such as high withstand voltage, high-temperature operation, large current density, high-speed switching, and low on-resistance can also be achieved as compared to a device being configured with a silicon semiconductor. In particular, an operation of high withstand voltage with low loss is possible, so that an excellent power device can be realized.

The Group III nitride semiconductor is a semiconductor obtained by combination of a Group III element and nitrogen, and representative examples thereof include aluminum nitride (AlN), gallium nitride (GaN), indium nitride (InN). Generally, it can be expressed as AlₓIn_{y}Ga_{1-x-y}N (0≦x≦1, 0≦y≦1, 0≦x+y≦1).

The nitride semiconductor device preferably further includes a fourth layer formed on the wall surface in the second layer and having a different conductive characteristic from that of the second layer.

According to this configuration, the wall surface in the second layer is formed with the fourth layer which is a region having a different conductive characteristic from that of the second layer. Thus, the gate insulating film is formed so as to contact the fourth layer, and the gate electrode is formed so as to face the fourth layer such that the gate insulating film is sandwiched between the gate electrode and the fourth layer.

Accordingly, during operation of the above-described MISFET, a region in which the inversion layer (channel) is formed is the fourth layer. As a result, when the fourth layer is a p-type semiconductor having a lower acceptor concentration than that of the second layer, for example, it is possible to keep a gate threshold voltage required for forming the inversion layer to a lower level, as compared to a case where a conductive characteristic of the region in which the inversion layer is formed is the same as that of the second layer. Therefore, the gate threshold voltage can be reduced, so that an excellent power device can be realized.

The fourth layer may be the p-type semiconductor having lower acceptor concentration than that of the above-described second layer. For example, any one of an n-type semiconductor, an i-type semiconductor, and a semiconductor which contains an n-type impurity and a p-type impurity may be possible. When the fourth layer is the n-type semiconductor, in order to realize the normally-off operation of the field effect transistor, a concentration of the n-type impurity can be appropriately controlled.

The nitride semiconductor device may be configured to further include a base layer supporting the nitride semiconductor structure, wherein the base layer comprises an insulating film having an opening for exposing a part of a main surface of the base layer, and the first layer is formed in a region extending from the opening to an upper area of the insulating film. The insulating film may be an insulating film is made of oxide silicon, silicon nitride, or silicon oxynitride, or combinations thereof.

The nitride semiconductor device may be configured to further include a base layer supporting the nitride semiconductor structure, wherein the base layer has a depression recessed from a main surface of the base layer, and the first layer is formed on the main surface of the base layer including an interior of the depression.

The base layer may include a sapphire substrate, and may include a conductive base layer being made of a conductive material. When the base layer includes a conductive base layer, the drain electrode may be formed on a surface of the conductive base layer on a side opposite from the first layer.

A manufacturing method for a nitride semiconductor device of the present invention includes: a structure formation step of forming a first layer made of an n-type Group III nitride semiconductor on a base layer, a second layer made of a p-type Group III nitride semiconductor on the first layer, and a third layer made of an n-type Group III nitride semiconductor on the second layer, to form a nitride semiconductor structure having a high dislocation region and a low dislocation region arranged along a direction parallel to a main surface of the base layer, a dislocation density of the low dislocation region being lower than that of the high dislocation region; a mesa structure formation step of forming a wall surface extending from the first, second, to third layers to form a mesa structure having a lateral surface which forms the wall surface in the low dislocation region; a gate insulating film formation step of forming a gate insulating film on the wall surface of the mesa structure to extend over the first, second, and third layers; a gate electrode formation step of forming a gate electrode so as to face the wall surface in the second layer such that the gate insulating film is sandwiched between the gate electrode and the wall surface; a drain electrode formation step of forming a drain electrode so as to be electrically connected to the first layer; and a source electrode formation step of forming a source electrode so as to be electrically connected to the third layer in the mesa structure. According to this method, the above-described nitride semiconductor device can be manufactured.

The manufacturing method for a nitride semiconductor device preferably further includes a fourth layer formation step of forming a fourth layer having a different conductive characteristic from that of the second layer on a semiconductor surface portion of the second layer exposed by the forming of the wall surface in the mesa structure formation step. According to this method, it is possible to manufacture the nitride semiconductor device further including the fourth layer formed on the wall surface in the second layer and having a different conductive characteristic from that of the second layer.

The structure formation step preferably includes: an insulating film formation step of forming an insulating film on the main surface of the base layer, the insulating film having an opening for exposing a part of the main surface of the base layer, and a step of forming the nitride semiconductor structure in a region extending from the opening to an upper area of the insulating film by growing a Group III nitride semiconductor from the opening using the insulating film as a mask. According to this method, it is possible to manufacture the nitride semiconductor device further including the base layer supporting the nitride semiconductor structure, wherein the base layer includes the insulating film having an opening for exposing a part of the main surface of the base layer and the first layer is formed in a region extending from the opening to an upper area of the insulating film.

The structure formation step preferably includes: a depression formation step of forming a depression on the main surface of the base layer by recessing the main surface of the base layer; and a step of forming the nitride semiconductor structure on the main surface of the base layer by growing a Group III nitride semiconductor from the main surface of the base layer comprising a main surface of an interior of the depression. According to this method, it is possible to manufacture the nitride semiconductor device further including the base layer supporting the nitride semiconductor structure, wherein the base layer has the depression recessed from the main surface of the base layer and the first layer is formed on the main surface of the base layer including the interior of the depression.

According to the method for manufacturing the nitride semiconductor device, it is preferable that the base layer comprises a substrate, and a conductive base layer formed on the substrate, the conductive base layer being made of a conductive material, and the drain electrode formation step comprises a step of removing the substrate, and a step of forming a drain electrode on a surface of the conductive base layer exposed by removing the substrate. According to this method, the drain electrode is formed on the surface of the conductive base layer exposed by the removal of the substrate, so that the drain electrode and the first layer can be electrically connected via the conductive base layer.

These and other objects, features and effects of the present invention will be more apparent from the following embodiments described with reference to the accompanying drawings.

### BRIEF DESCRIPTION OF THE DRAWINGS

FIG. 1 is a diagrammatic cross-sectional view for describing a structure of a field effect transistor according to a first embodiment of the present invention;

FIG. 2A is a diagrammatic cross-sectional view showing a method for manufacturing the field effect transistor in FIG. 1 according to a sequence of steps;

FIG. 2B is a diagram showing a step subsequent to that in FIG. 2A;

FIG. 2C is a diagram showing a step subsequent to that in FIG. 2B;

FIG. 2D is a diagram showing a step subsequent to that in FIG. 2C;

FIG. 2E is a diagram showing a step subsequent to that in FIG. 2D;

FIG. 2F is a diagram showing a step subsequent to that in FIG. 2E;

FIG. 2G is a diagram showing a step subsequent to that in FIG. 2F;

FIG. 2H is a diagram showing a step subsequent to that in FIG. 2G;

FIG. 2I is a diagram showing a step subsequent to that in FIG. 2H;

FIG. 2J is a diagram showing a step subsequent to that in FIG. 2I;

FIG. 3 is a diagrammatic cross-sectional view for describing a structure of a field effect transistor according to a second embodiment of the present invention;

FIG. 4A is a diagrammatic cross-sectional view showing a method for manufacturing the field effect transistor in FIG. 3 according to a sequence of steps;

FIG. 4B is a diagram showing a step subsequent to that in FIG. 4A;

FIG. 4C is a diagram showing a step subsequent to that in FIG. 4B;

FIG. 4D is a diagram showing a step subsequent to that in FIG. 4C;

FIG. 4E is a diagram showing a step subsequent to that in FIG. 4D;

FIG. 4F is a diagram showing a step subsequent to that in FIG. 4E;

FIG. 4G is a diagram showing a step subsequent to that in FIG. 4F;

FIG. 4H is a diagram showing a step subsequent to that in FIG. 4G;

FIG. 4I is a diagram showing a step subsequent to that in FIG. 4H;

FIG. 4J is a diagram showing a step subsequent to that in FIG. 4I; and

FIG. 5 is a diagrammatic cross-sectional view for describing a structure of a field effect transistor according to a third embodiment of the present invention.

### BEST MODE FOR CARRYING OUT THE INVENTION

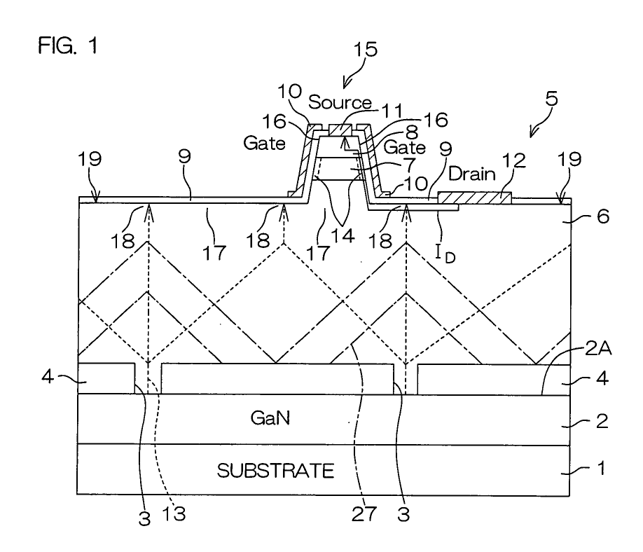

FIG. 1 is a diagrammatic cross-sectional view for describing a structure of a field effect transistor according to a first embodiment of the present invention.

The field effect transistor is provided with: a substrate 1 (base layer); a GaN film 2 (base layer, conductive base layer) grown on the substrate 1; an insulating film mask 4 (insulating film) which is formed on a main surface 2A of the GaN film 2 and has an opening 3 for exposing a part of the main surface 2A; and a nitride semiconductor laminated structure 5 (nitride semiconductor structure) formed in a region from the opening 3 of the insulating film mask 4 to an upper area of the insulating film mask 4.

For the substrate 1, an insulative substrate such as a sapphire substrate or the like, or a conductive substrate such as a GaN substrate, a ZnO substrate, Si substrate, a GaAs substrate, SiC substrate or the like, may be applied, for example.

The GaN film 2 is one example of a Group III nitride semiconductor compound expressed by InₓAl_{y}Ga_{1-x-y}N (0≦x≦1, 0≦y≦1, 0≦x+y≦1), for example, and has a function as a buffer layer laminated on the substrate 1. The GaN film 2 may or may not contain a dopant (n-type or p-type). By lamination of the GaN film 2 on the substrate 1 one can preferably regrow the nitride semiconductor laminated structure 5 on the GaN film 2.

The insulating film mask 4 can be configured using an oxide or nitride, and examples thereof include: silicon oxide (SiO₂); gallium oxide (Ga₂O₃); magnesium oxide (MgO); scandium oxide (Sc₂O₃); silicon nitride (SiN); silicon oxynitride (SiON), or the like. Among those materials, the insulating film mask 4 may preferably be configured by the oxide silicon (SiO₂), the silicon nitride (SiN), or the silicon oxynitride (SiON), or a combination thereof.

The nitride semiconductor laminated structure 5 is provided with: an n-type GaN layer 6 (first layer); a p-type GaN layer 7 (second layer); and an n-type GaN layer 8 (third layer). Each GaN layer is laminated in this order. More specifically, each GaN layer is formed by epitaxially growing the Group III nitride semiconductor on the GaN film 2 according to a metal organic chemical vapor deposition (MOCVD method), a liquid phase epitaxial growth method (LPE method), a vapor phase epitaxial growth method (VPE method), a molecular beam epitaxial growth method (MBE method), or the like. For example, the n-type GaN layer 6 is formed by growing from the opening 3 of the insulating film mask 4 toward a direction indicated by a growth surface 27. At a step of growing the n-type GaN layer 6, a dislocation defect is generated along a growth direction of the growth surface 27. As a result, in an interior of the nitride semiconductor laminated structure 5 (an interior of the n-type GaN layer 6), dislocation defects 13 are generated at a plurality of locations (above the opening 3 and at an upper center of the insulating film mask 4, for example) along a direction perpendicular to a main surface of the substrate 1. According to the locations at which the dislocation defects 13 are present, along a direction parallel to the main surface of the substrate 1 the nitride semiconductor laminated structure 5 is distinguished between high dislocation regions 18 (portions in which the dislocation defects 13 are present) in which a dislocation density is high and low dislocation regions 17 (portions in which the dislocation defects 13 are not present) in which a dislocation density is lower than that of the high dislocation regions 18.

The nitride semiconductor laminated structure 5 is etched to a depth such that the n-type GaN layer 8 to the n-type GaN layer 6 are exposed in a direction transversing an interface between the laminated layers to have a mesa-like laminated portion 15 (mesa structure) in the low dislocation region 17.

The mesa-like laminated portion 15 is formed to be trapezoidal in cross section (mesa shape) in FIG. 1, and a lateral surface thereof configures a wall surface 16 which extends from the n-type GaN layer 6, the p-type GaN layer 7, to the n-type GaN layer 8.

The wall surface 16 is a surface inclined with respect to the main surface of the substrate 1, within a range of 15 to 90 degrees for example. For example, when the main surface of the substrate 1 is a c-surface (0001), the GaN film 2 and the nitride semiconductor laminated structure 5 grown on the substrate 1 by an epitaxial growth, i.e., the n-type GaN layer 6, the p-type GaN layer 7, and the n-type GaN layer 8, are laminated using the c-surface (0001) again as a main surface. Therefore, the wall surface 16 which is the surface inclined within a range of 15 to 90 degrees with respect to the main surface (c-surface) becomes a non-polar surface such as an m-surface (10-10) or an a-surface (11-20), or a semi-polar surface such as (10-13), (10-11), (11-22), or the like. That is, when the wall surface 16 is the semi-polar surface or the like, a shape of the mesa-like laminated portion 15 is formed to be trapezoidal in cross section (see FIG. 1) while when the wall surface 16 is the non-polar surface, the shape of the mesa-like laminated portion 15 is formed to be rectangular in cross section.

A region 14 is formed in the vicinity of the wall surface 16 in the p-type GaN layer 7. The region 14 is made of a semiconductor having a different conductive characteristic from that of the p-type GaN layer 7, e.g., a p⁻-type semiconductor having an acceptor concentration lower than that of the p-type GaN layer 7. A thickness of the region 14 in a direction orthogonal to the wall surface 16 is several nm to 100 nm, for example. Insofar as a semiconductor which has a different conductive characteristic from that of the p-type GaN layer 7 is used, the region 14 is not limited to the p-type semiconductor, but may include a semiconductor such as an n-type semiconductor containing an n-type impurity, an i-type semiconductor containing almost no impurity, a semiconductor containing n-type and p-type impurities, for example. In the vicinity of a surface of the region 14, when an appropriate bias voltage is applied to a gate electrode 10 (described later), an inversion layer (channel) is formed which connects electrically between the n-type GaN layers 6 and 8.

Along with the formation of the mesa-like laminated portion 15, the n-type GaN layer 6 is formed with extracted sections 19 extracted from both sides of the mesa-like laminated portion 15 in a lateral direction (hereinafter, referred to as a “width direction”) parallel to the interface between the laminated layers of the nitride semiconductor laminated structure 5. That is, in this embodiment, each extracted section 19 is configured with an extended section of the n-type GaN layer 6.

In the low dislocation region 17 on a surface of the extracted section 19, a drain electrode 12 is formed in a contacting manner. Accordingly, the drain electrode 12 is electrically connected to the n-type GaN layer 6. The drain electrode 12 serves its function as long as it is conducted with (electrically connected to) the n-type GaN layer 6. For example, a further n-type semiconductor layer may be configured to interpose between the extracted section 19 and the drain electrode 12.

A source electrode 11 is formed on the n-type GaN layer 8. As a result, the source electrode 11 is electrically connected to the n-type GaN layer 8.

A gate insulating film 9 is formed on a top surface (other than a formation region of the drain electrode 12) of the n-type GaN layer 6 and the wall surface 16 and those of the n-type GaN layer 8 (other than a formation region of the source electrode 11). On the gate insulating film 9, a gate electrode 10 is formed so as to face the region 14 such that the gate insulating film 9 is sandwiched between the gate electrode 10 and the region 14.

The gate insulating film 9 can be configured using an oxide or nitride, for example. More specifically, silicon oxide (SiO₂), gallium oxide (Ga₂O₃), magnesium oxide (MgO), scandium oxide (Sc₂O₃), silicon nitride (SiN), or the like, may be used to configure the gate insulating film 9.

The gate electrode 10 may be configured using a conductive material, such as platinum (Pt), aluminum (Al), a nickel-gold alloy (Ni—Au alloy), a nickel-titanium-gold alloy (Ni—Ti—Au alloy), a palladium-gold alloy (Pd—Au alloy), a palladium-titanium-gold alloy (Pd—Ti—Au alloy), a palladium-platinum-gold alloy (Pd—Pt—Au alloy), polysilicon.

The drain electrode 12 is preferably configured using a metal which contains at least Al. For example, a Ti—Al alloy may be used to configure the drain electrode 12. Similar to the drain electrode 12, the source electrode 11 is also preferably configured using a metal which contains Al. For example, the Ti—Al alloy may be used to configure the source electrode 11. When the drain electrode 12 and the source electrode 11 are configured with the metal which contains Al, an excellent contact with a wiring layer (not shown) can be achieved. In addition, the drain electrode 12 and the source electrode 11 may be configured using Mo or a Mo compound (molybdenum silicide, for example); or Ti or a Ti compound (titanium silicide, for example); or W or a W compound (tungsten silicide, for example).

Subsequently, an operation of the field effect transistor is described.

First, a voltage is applied to the source electrode 11 and the drain electrode 12 such that the drain electrode 12 is positive. Accordingly, a pn junction at an interface between the n-type GaN layer 6 and the p-type GaN layer 7 is applied a reverse voltage. As a result, between the n-type GaN layer 8 and the n-type GaN layer 6, i.e., source and drain, are nonconductive state. From this state, when a bias voltage of a predetermined voltage value (gate threshold voltage) or more which is positive with respect to the region 14 is applied to the gate electrode 10, electrons are induced in the vicinity of the surface of the region 14 to form the inversion layer (channel). Via the inversion layer, conduction is provided between the n-type GaN layer 6 and the n-type GaN layer 8 in the mesa-like laminated portion 15. Thus, the source and drain are conducted each other, so that a current flows in a direction of an arrow I_{D} shown in FIG. 1. At this time, the region 14 is made of a p⁻-type semiconductor of which an acceptor concentration is lower than that of the p-type GaN layer 7, whereby the electrons can be induced in the region 14 with a lower gate threshold voltage. When a p-type impurity concentration of the region 14 is appropriately defined, if an appropriate bias is applied to the gate electrode 10, the source and drain are conducted each other. In contrast, if the bias is not applied to the gate electrode 10, the source and drain are nonconductive each other. That is, a normally-off operation is realized.

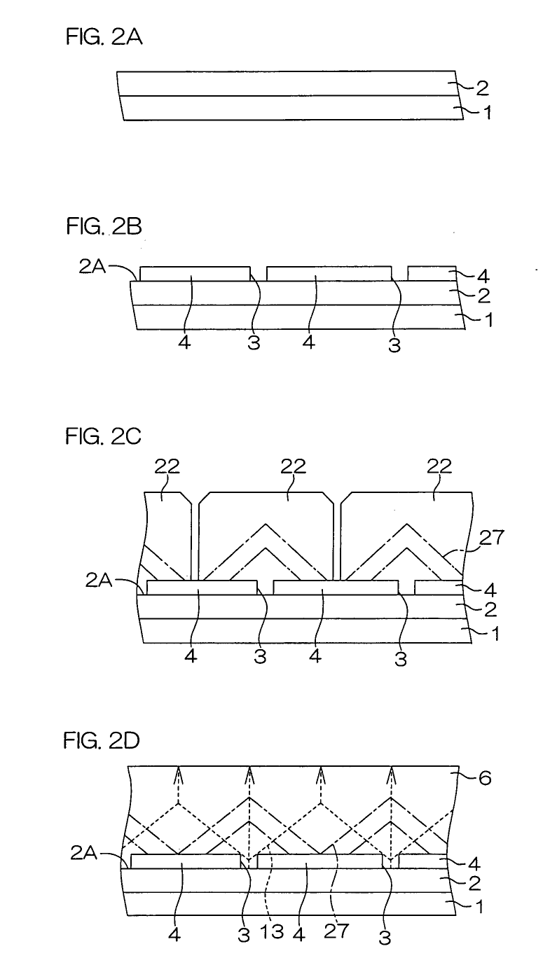

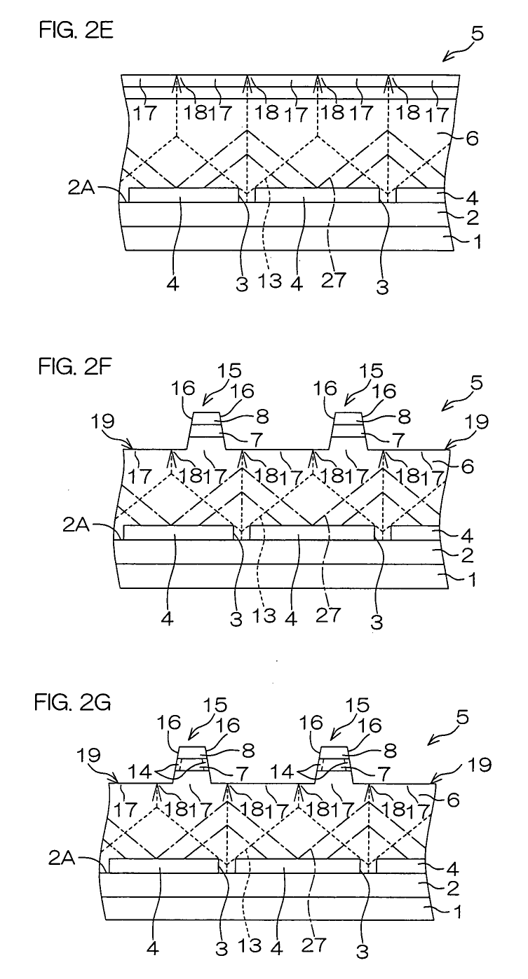

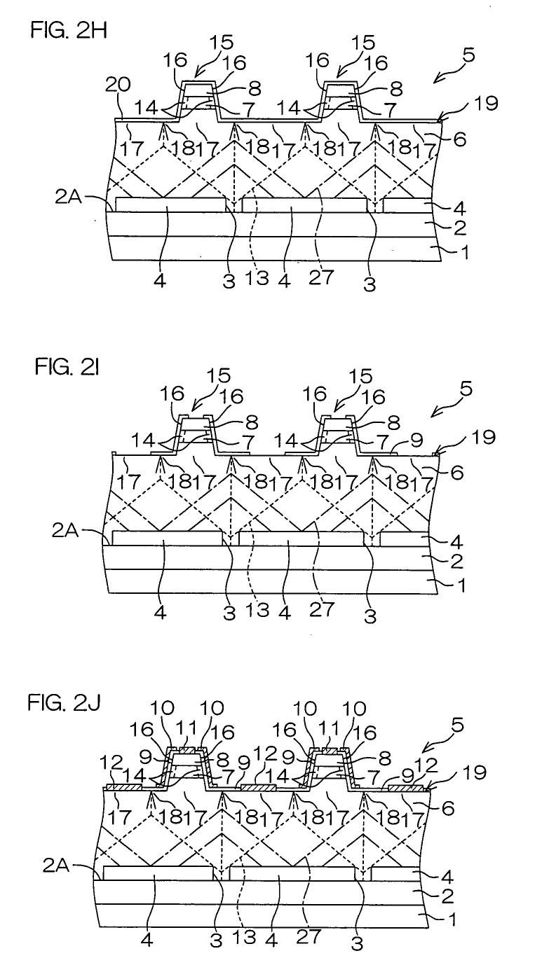

FIG. 2A to FIG. 2J are diagrammatic cross-sectional views showing a method for manufacturing the field effect transistor in FIG. 1 according to a sequence of steps.

In manufacturing of the field effect transistor, as shown in FIG. 2A, the GaN film 2 is first epitaxially grown on the substrate 1 using the c-surface (0001) as the main surface, for example. A method for growing the GaN film 2 includes the above-described metal organic chemical vapor deposition (MOCVD method), liquid phase epitaxial growth method (LPE method), vapor phase epitaxial growth method (VPE method), molecular-beam epitaxial growth method (MBE method) or the like. When the GaN film 2 is epitaxially grown, if the n-type dopant is contained, Si may be used. If the p-type dopant is contained, Mg, C, or the like may be used.

Subsequently, on the GaN film 2, an insulating film (not shown) which is for the insulating film mask 4 is laminated so as to cover an entire surface of the GaN film 2 according to a plasma-enhanced chemical vapor deposition (plasma CVD method), for example. Thereafter, this insulating film is etched by dry etching, for example, to form the insulating film mask 4 having the opening 3 (insulting film formation step), as shown in FIG. 2B.

Subsequently, from the main surface 2A of the GaN film 2, which is exposed from the opening 3, the n-type GaN layer 6 is epitaxially grown. More specifically, under conditions (growth temperature, intra-chamber pressure, or the like) that a GaN compound semiconductor tends to grow in a vertical direction, a crystal growth of the GaN compound semiconductor is performed using an exposed part of the GaN film 2 as a nucleus. Thereafter, this GaN compound semiconductor is grown in the lateral direction under conditions (growth temperature, intra-chamber pressure, or the like) that the GaN compound semiconductor tends to grow in the lateral direction (see the growth surface 27 in FIG. 2C).

Accordingly, as shown in FIG. 2C, a plurality (three in FIG. 2C) of stripe-shaped GaN compound semiconductor layers 22 each having a flat top face are formed. Through this state, adjacent layers of the plurality of GaN compound semiconductor layers 22 are joined each other to obtain the integrated n-type GaN layer 6 as shown in FIG. 2D. For the n-type dopant for epitaxially growing the n-type GaN layer 6, Si may be used, for example. During the growth of the n-type GaN layer 6, the dislocation defect generated resulting from the mismatch between a lattice constant of the substrate 1 and that of the GaN film 2 is transmitted in an interior of the GaN compound semiconductor along the growth direction of the growth surface 27, and in a state where the n-type GaN layer 6 is formed, the dislocation defect is transmitted in an interior of the n-type GaN layer 6 along a direction orthogonal to the main surface of the substrate 1. Therefore, the dislocation defects 13 are generated at a plurality of locations (above the opening 3 and above a center of the insulating film mask 4, for example) in the interior of the n-type GaN layer 6.

After the formation of the n-type GaN layer 6, as shown in FIG. 2E, the p-type GaN layer 7 and the n-type GaN layer 8 are grown in this order on the n-type GaN layer 6 to obtain the nitride semiconductor laminated structure 5 made of the n-type GaN layer 6, the p-type GaN layer 7, and the n-type GaN layer 8. As in the growth of these GaN layers, the dislocation defect 13 generated in the n-type GaN layer 6 is transmitted in the interiors of the p-type GaN layer 7 and the n-type GaN layer 8. Therefore, in the interior of the nitride semiconductor laminated structure 5, the dislocation defects 13 which penetrate each laminated GaN layer in a layer thickness direction are present. According to the locations at which the dislocation defects 13 are present, along a direction parallel to the main surface of the substrate 1, the nitride semiconductor laminated structure 5 is distinguished between high dislocation regions 18 (portions in which the dislocation defects 13 are present) of which a dislocation density is high and low dislocation regions 17 (portions in which the dislocation defects 13 are not present) of which a dislocation density is lower than that of the high dislocation regions 18.

Subsequently, as shown in FIG. 2F, in order to form the mesa-like laminated portion 15 in the low dislocation region 17, the nitride semiconductor laminated structure 5 is etched to be in a stripe shape so that the wall surface 16 having a surface orientation inclined within a range of 15 to 90 degrees with respect to the c-surface (0001) is cut (mesa structure formation step). As a result, the wall surface 16 is formed that extends from the n-type GaN layer 8 through the p-type GaN layer 7 to a layer thickness middle section of the n-type GaN layer 6, and the mesa-like laminated portion 15 and the extracted section 19 made of the extended section of the n-type GaN layer 6 are simultaneously formed in the nitride semiconductor laminated structure 5.

The formation of the wall surface 16 may be performed by dry etching (anisotropic etching) using a chlorine gas, for example. Thereafter, a wet etching process may be further performed, if necessary, to improve the wall surface 16 damaged by the dry etching. For the wet etching process, potassium hydroxide (KOH), aqueous ammonia, or the like are preferably used. The application of the wet etching process removes a surface layer of the damaged wall surface 16 to obtain a less damaged wall surface 16. Reduction of the damage of the wall surface 16 can maintain a preferable crystal state of the region 14 to result in a preferable interface between the wall surface 16 and the gate insulating film 9. As a result, an interface state level can be reduced. Thus, a channel resistance can be reduced and a leak current can also be suppressed. Instead of the wet etching process, a dry etching process of low damage may also be applied.

Subsequently, on the nitride semiconductor laminated structure 5, the gate insulating film 9 is formed by an ECR (Electron Cyclotron Resonance) sputtering method, for example. In the formation of the gate insulating film 9 by the ECR sputtering method, the substrate 1 on which the nitride semiconductor laminated structure 5 is formed is first placed in an ECR film deposition apparatus, and is irradiated with an Ar⁺ plasma having an energy of about 30 eV for several seconds, for example. Irradiation of the Ar⁺ plasma alters a region near the wall surface 16 in the p-type GaN layer 7, as shown in FIG. 2G, to form the region 14 of the p⁻-type semiconductor having a different conductive characteristic from that of the p-type GaN layer 7, e.g., having a lower acceptor concentration than that of the p-type GaN layer 7 (fourth layer formation step).

Subsequently, as shown in FIG. 2H, an insulting film 20 (silicon oxide, gallium oxide, or the like) which covers the entire surface of the nitride semiconductor laminated structure 5 is formed. Then, after the formation of the insulating film 20, as shown in FIG. 2I, an unnecessary part of the insulating film (part other than the gate insulating film 9) is etched away to form the gate insulating film 9 (gate insulating film formation step). The formation method of the gate insulating film 9 is not limited to the ECR sputtering method, but may include a magnetron sputtering method or the like. If we use a certain formation method and formation condition of the gate insulating film 9, in formation of the gate insulating film 9, the wall surface 16 in the p-type GaN layer 7 is ion-implanted with sputtering particles, such as oxygen which are an n-type impurity. Thus, also at formation of the gate insulating film 9, a region near the wall surface 16 in the p-type GaN layer 7 is altered. That is, a step of forming the region 14 and that of forming the gate insulating film 9 are simultaneously performed.

After the formation of the gate insulating film 9, according to a well-known photolithography technique, a photoresist (not shown) having an opening in a region where the gate electrode 10, the drain electrode 12, and the source electrode 11 should be formed is formed on the insulating film 9. Then, a metal (platinum, aluminum, or the like, for example) used for materials of these electrodes (10, 12, and 11) is formed according to a sputtering method or the like. Thereafter, when the photoresist is removed, an unnecessary part of the metal (part other than the electrodes (10, 12, and 11)) together with the photoresist are lifted-off. As a result, as shown in FIG. 2J, the gate electrode 10 is formed to face the region 14 so that the gate insulating film 9 is sandwiched between the gate electrode 10 and the region 14 (gate electrode formation step). In addition, the drain electrode 12 is formed so as to contact the top surface of the extracted section 19 (the extended section of the n-type GaN layer 6), and the source electrode 11 is formed so as to contact the top surface of the n-type GaN layer 8 (drain electrode formation step and source electrode formation step).

As described above, the field effect transistor of the structure shown in FIG. 1 can be obtained.

In the above-described manufacturing steps, the region 14 is formed at the formation step of the gate insulating film 9. However, the region 14 can also be formed by altering a region near the wall surface 16 in the p-type GaN layer 7 by providing, besides the formation step of the gate insulating film 9, a step of irradiating a region of the wall surface 16 in the p-type GaN layer 7 with a plasma or an electron beam or a step of applying an ion-implantation to a region of the wall surface 16 in the p-type GaN layer 7, for example.

In FIG. 1, the region 14 is shown only in the wall surface 16 in the p-type GaN layer 7. In reality, the altered region is formed also in the wall surface 16 in the n-type GaN layer 6 or the n-type GaN layer 8. However, even when the altered region is formed in the wall surface 16 in the n-type GaN layer 6 or the n-type GaN layer 8, there is no change on the effect as a device. Therefore, the altered region is omitted in FIG. 1.

The plurality of nitride semiconductor laminated structures 5 formed in a stripe shape on the substrate 1 each form a unit cell. Each gate electrode 10, each drain electrode 12, and each source electrode 11 of the plurality of nitride semiconductor laminated structures 5 are respectively connected commonly at locations not shown. The drain electrode 12 may be shared between the adjacent nitride semiconductor laminated structures 5.

As described above, according to the embodiment, the mesa-like laminated portion 15 is formed in the low dislocation region 17, among the high dislocation region 18 and the low dislocation region 17 formed in the nitride semiconductor laminated structure 5. That is, in a region where a current flows during operation of the field effect transistor, almost no dislocation defects 13 are present. It is therefore possible to reduce a generation of a leak current in the field effect transistor. As a result, a lowering in electrical characteristics of the field effect transistor can be suppressed, so that such a field effect transistor can realize an excellent power device.

In more detail the high dislocation region 18 is present in a region from the drain electrode 12 to an interface with the region 14 of the n-type GaN layer 6. However, in spite of this, a direction of the dislocation defect 13 and that (Id) of a current which flows in the source-to-drain path are different (approximately perpendicular) to each other. Therefore, almost no leak flow is generated resulting therefrom.

The field effect transistor has a vertical transistor structure in which the n-type GaN layer 6, the p-type GaN layer 7, and the n-type GaN layer 8 are laminated. Consequently, the normally-off operation, i.e., an operation in which the source-to-drain path are an off state when no bias is applied to the gate electrode 10, can also be easily realized. As a result of integration, a large amount of current can flow easily, and thickening of the n-type GaN layer 6 can also secure high withstand voltage easily. Therefore, an effective power device can be provided. Of course, when the field effect transistor is configured with the n-type GaN layer 6, the p-type GaN layer 7, and the n-type GaN layer 8, each of which are made of the Group III nitride semiconductor, characteristics such as high withstand voltage, high-temperature operation, large current density, high-speed switching, and low on-resistance can also be achieved as compared to a device made of a silicon semiconductor. In particular, an operation of high withstand voltage with low loss is possible, so that an excellent power device can be realized.

When the structure is adopted in which the gate insulating film 9 is formed so as to contact the region 14 formed on the surface exposed to the wall surface 16 in the p-type GaN layer 7, a gate threshold voltage required for forming the inversion layer can be reduced. As a result, while the acceptor concentration of the p-type GaN layer 7 is kept high so as to avoid generation of reach-through breakdown, the gate threshold voltage can be decreased, so that an excellent transistor operation can be performed, thereby realizing an excellent power device.

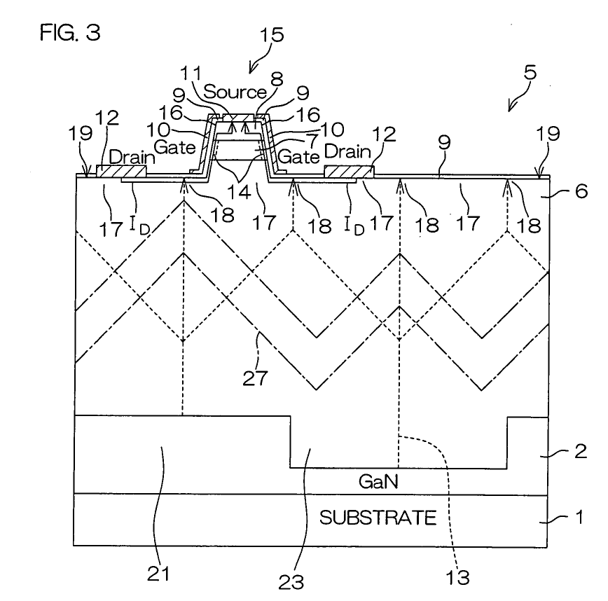

FIG. 3 is a diagrammatic cross-sectional view for describing a structure of a field effect transistor according to a second embodiment of the present invention. In FIG. 3, parts corresponding to those in the preceding FIG. 1 are designated by the same reference numerals as those in FIG. 1.

In this embodiment, no insulating film mask 4 is formed on the main surface 2A of the GaN film 2, and the GaN film 2 is formed with a depression 23 by etching to a certain film thickness of the GaN film 2 from the main surface 2A. The depression 23 is formed to form protrusions 21 higher by a step level than the depression 23 on both sides of the depression 23 in the GaN film 2.

The nitride semiconductor laminated structure 5 is formed on a region which extends from the depression 23 to upper areas of the protrusions 21, i.e., an entire surface of the GaN film 2. In the interior of the nitride semiconductor laminated structure 5 (interior of the n-type GaN layer 6), similarly to the case in FIG. 1, the dislocation defects 13 are generated at a plurality of locations (above the depression 23 and above a center of the protrusion 21, for example) along a direction perpendicular to the main surface of the substrate 1. Therefore, along the direction parallel to the main surface of the substrate 1, the nitride semiconductor laminated structure 5 in the field effect transistor in FIG. 3 is also distinguished between the high dislocation regions 18 (portions in which the dislocation defects 13 are present) of which a dislocation density is high and the low dislocation regions 17 (portions in which the dislocation defects 13 are not present) of which a dislocation density is lower than that of the high dislocation regions 18.

Similarly to the case in FIG. 1, the mesa-like laminated portion 15 is also formed in the low dislocation region 17. The rest of the configuration is similar to that in the case of the preceding first embodiment. According to this configuration, an operation similar to that in the first embodiment is again possible, and an effect similar to that in the first embodiment can also be obtained.

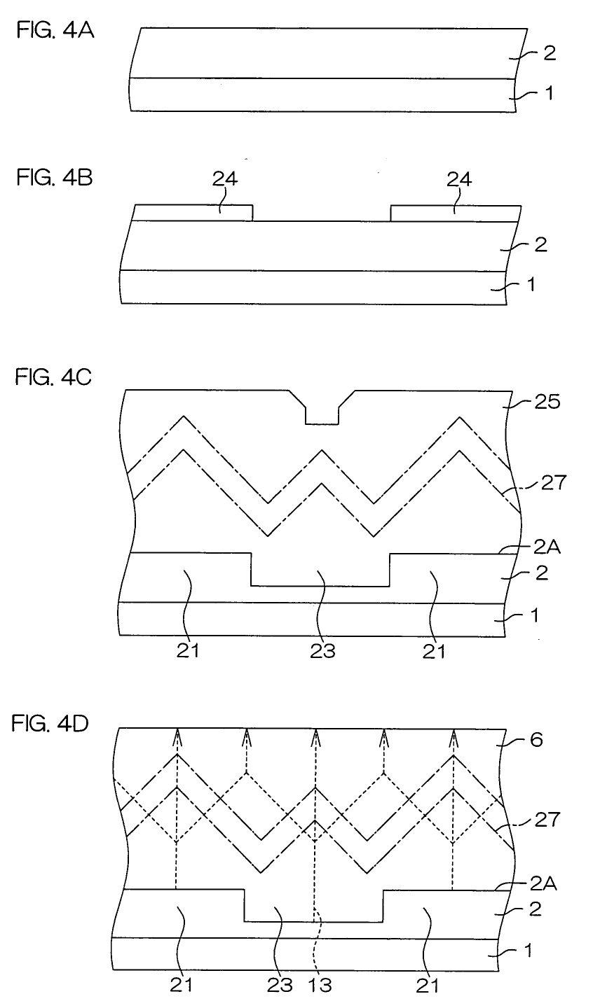

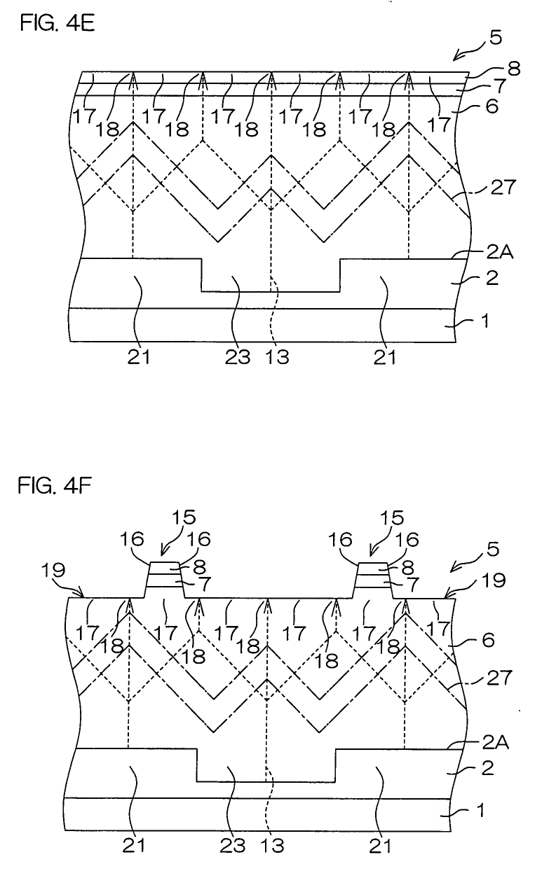

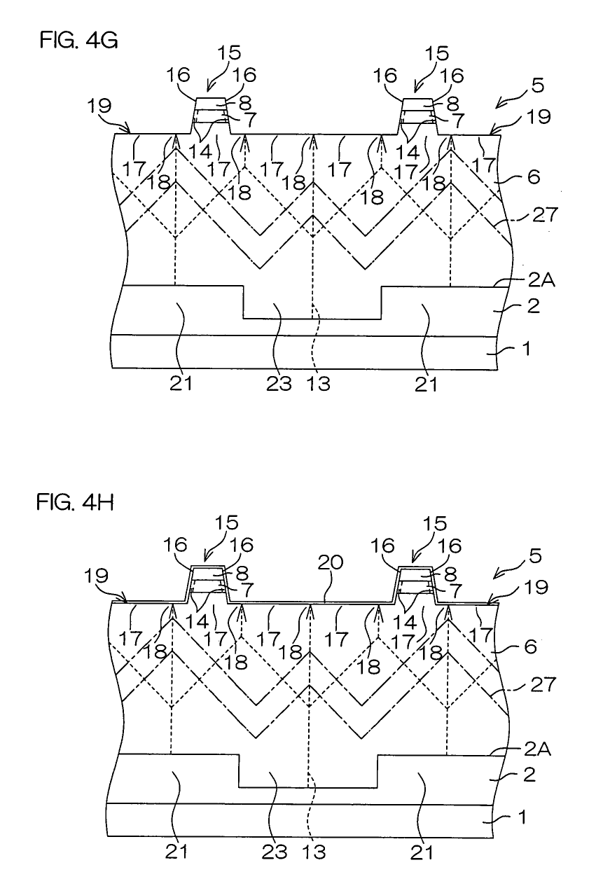

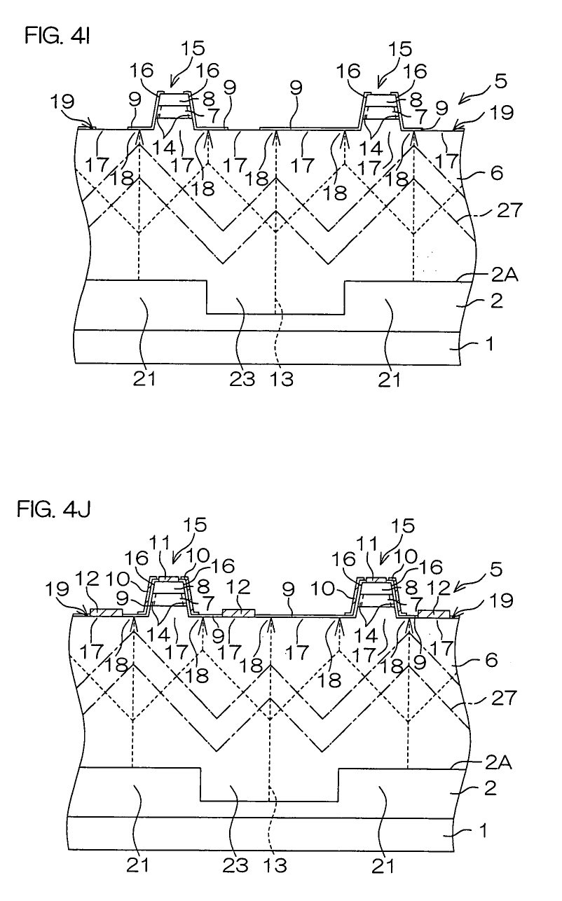

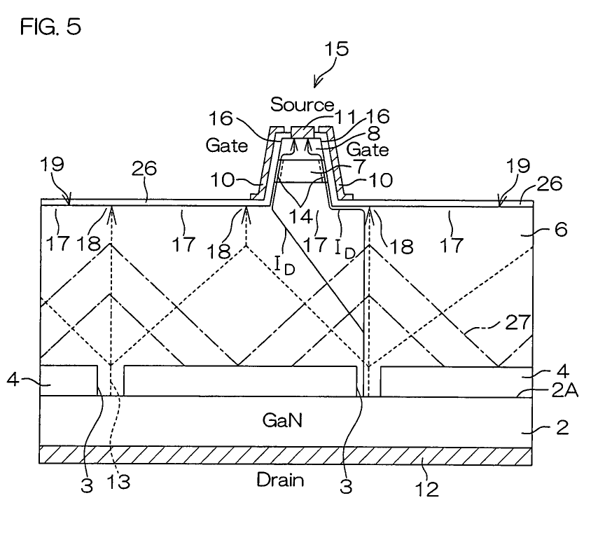

FIG. 4A to FIG. 4J are diagrammatic cross-sectional views each showing a method for manufacturing the field effect transistor in FIG. 3 according to a sequence of steps.

In manufacturing of the field effect transistor, as shown in FIG. 4A, the GaN film 2 is first epitaxially grown on the substrate 1 using the c-surface (0001) as the main surface, for example.

Subsequently, as shown in FIG. 4B, a photoresist 24 having an opening which corresponds to the depression 23 is formed on the GaN film 2. More specifically, a photoresist is first applied on an entire surface of the GaN film 2 and patterned by photolithography. As a result, the photoresist 24 having an opening which corresponds to the depression 23 is formed. After the formation of the photoresist 24, the GaN film 2 exposed from the opening is etched by dry etching, for example, and the remaining photoresist 24 on the GaN film 2 is melted and removed (depression formation step). Accordingly, the depression 23 is formed, and a plurality (two in this embodiment) of protrusions 21 are formed in a stripe shape.

Subsequently, the n-type GaN layer 6 is epitaxially grown from the main surface 2A of the GaN film 2 including the depression 23. As a result, as shown in FIG. 4C, stripe-shaped GaN compound semiconductor layers 25 each having a flat top face are formed. Through this state, adjacent layers of a plurality of GaN compound semiconductor layers 25 are further joined each other to obtain the integrated n-type GaN layer 6, as shown in FIG. 4D. At this time, similarly to the case in FIG. 2D, the dislocation defect is also transmitted in the interior of the GaN compound semiconductor along the growth direction of the growth surface 27. Therefore, the dislocation defects 13 are generated at a plurality of locations (above the depression 23 and above the center of the protrusion 21, for example) in the interior of the n-type GaN layer 6.

After the formation of the n-type GaN layer 6, as shown in FIG. 4E, the p-type GaN layer 7 and the n-type GaN layer 8 are grown in this order on the n-type GaN layer 6 to obtain the nitride semiconductor laminated structure 5. As in the growth of these GaN layers, similarly to the case of FIG. 2E, the dislocation defects 13 are generated in the nitride semiconductor laminated structure 5. Therefore, according to locations at which the dislocation defects 13 are present, along the direction parallel to the main surface of the substrate 1, the nitride semiconductor laminated structure 5 is distinguished between the high dislocation regions 18 (portions in which the dislocation defects 13 are present) of which a dislocation density is high and the low dislocation regions 17 (portions in which the dislocation defects 13 are not present) of which a dislocation density is lower than that of the high dislocation regions 18.

Subsequently, as shown in FIG. 4F, in order to form the mesa-like laminated portion 15 in the low dislocation region 17, the nitride semiconductor laminated structure 5 is etched to be in a stripe shape so that the wall surface 16 having a surface orientation inclined within a range of 15 to 90 degrees with respect to the c-surface (0001) is cut (mesa structure formation step). As a result, the mesa-like laminated portion 15 and the extracted section 19 made of the extended section of the n-type GaN layer 6 are simultaneously formed in the nitride semiconductor laminated structure 5. The formation method of the wall surface 16 is similar to that in the case of the above-described manufacturing method.

Subsequently, according to the method similar to that in the case of the above-described manufacturing method (the ECR sputtering method, for example), the gate insulating film 9 is formed on the nitride semiconductor laminated structure 5. That is, in the formation of the gate insulating film 9, irradiation of an Ar⁺ plasma alters a region near the wall surface 16 in the p-type GaN layer 7, as shown in FIG. 4G, to form the region 14 of the P⁻-type semiconductor having a different conductive characteristic from that of the p-type GaN layer 7, e.g., having a lower acceptor concentration than that of the p-type GaN layer 7 (fourth layer formation step). As shown in FIG. 4H, the insulating film 20 which covers the entire surface of the nitride semiconductor laminated structure 5 is formed.

After the formation of the insulating film 20, as shown in FIG. 4I, an unnecessary part of the insulating film 20 (a part other than the gate insulating film 9) is etched away to form the gate insulating film 9 (gate insulating film formation step). The gate electrode 10, the source electrode 11, and the drain electrode 12 are formed according to a method similar to the above-described manufacturing method (gate electrode formation step, drain electrode formation step, and source electrode formation step).

As described above, the field effect transistor of the structure shown in FIG. 3 can be obtained.

The plurality of nitride semiconductor laminated structures 5 formed in a stripe shape on the substrate 1 each form a unit cell. The gate electrodes 10, the drain electrodes 12, and the source electrodes 11 of the plurality of nitride semiconductor laminated structures 5 are each commonly connected at a location not shown. The drain electrode 12 may be shared between the adjacent nitride semiconductor laminated structures 5.

FIG. 5 is a diagrammatic cross-sectional view for describing a structure of a field effect transistor according to a third embodiment of the present invention. In FIG. 5, parts corresponding to those in the preceding FIG. 1 are designated with same reference numerals as those in FIG. 1.

In this embodiment, the substrate 1 is not provided, and on a surface opposite to a side on which the nitride semiconductor laminated structure 5 in the GaN film 2 is formed, the drain electrode 12 is formed in a manner to contact the above-described surface. More specifically, the drain electrode 12 is deposited so as to cover almost the entire region of a bottom surface of the GaN film 2. Therefore, in this embodiment, the drain electrode 12 is electrically connected via the GaN film 2 to the n-type GaN layer 6.

The top surface of the n-type GaN layer 6 and the wall surface 16 and those of the n-type GaN layer 8 (other than a formation region of the source electrode 11) in the nitride semiconductor laminated structure 5 are formed with the gate insulating film 26. Further, the gate electrode 10 is formed on the gate insulating film 26 so as to face the region 14 such that the gate insulating film 26 is sandwiched between the gate electrode 10 and the region 14. The rest of the configuration is similar to that in the case of the preceding first embodiment.

In the field effect transistor, even when an insulative substrate is used in the growth of the GaN film 2, the vertically structured field effect transistor can be realized. Further, since the insulative substrate is removed, a resistance of the substrate during operation of the transistor can be reduced. Electrons flown into the n-type GaN layer 6 are diffused to flow in a wide range of the n-type GaN layer 6, to flow into the drain electrode 12. Therefore, concentration of current can be suppressed. Further, according to this configuration, an operation similar to that in the first embodiment is possible, and an effect similar to that in the first embodiment can be obtained.

The field effect transistor can be manufactured according to a method similar to that described with reference to FIGS. 2A to 2J. In this case, for example, at the step shown in FIG. 2I, the unnecessary part of the insulating film (part other than the gate insulating film 26) is removed by etching, so that the gate insulating film 26 is formed (gate insulating film formation step). After the step shown in FIG. 2I, the substrate 1 is removed according to a laser lift-off method, a CMP (chemical-mechanical polishing) process, an etching process, or the like, so that the surface of the GaN film 2 is exposed. The drain electrode 12 is formed on the exposed surface of the GaN film 2 in a contacting manner. The remaining steps are similar to the case of the above-described first embodiment.

As described above, the embodiments of the present invention are described, and the present invention can further be implemented by another embodiment.

For example, in the third embodiment, the configuration is shown in which the configuration of the first embodiment is modified and the substrate 1 is removed (see FIG. 5). Further in the field effect transistor according to the second embodiment, a configuration may be adopted in which the substrate 1 is removed.

Although the embodiments of the present invention are described in detail, these embodiments are merely specific examples used for clarifying the technical contents of the present invention. Therefore, the present invention should not be construed as being limited in any way to these specific examples. The spirit and scope of the present invention are limited only by the scope of the appended claims.

This application corresponds to Japanese Patent Application No. 2007-45217 filed with the Japanese Patent Office on Feb. 26, 2007, the full disclosure of which is incorporated herein by reference.

What is claimed is:

1. A nitride semiconductor device, comprising:
a nitride semiconductor structure comprising an n-type first layer, a p-type second layer provided on the first layer, and an n-type third layer provided on the second layer, each layer of the nitride semiconductor structure being made of a Group III nitride semiconductor, the nitride semiconductor structure comprising a mesa structure having a lateral surface which forms a wall surface extending from the first, second, to third layers;
a gate insulating film formed on the wall surface of the mesa structure such that the gate insulating film extends over the first, second, and third layers;
a gate electrode formed as facing the wall surface in the second layer with the gate insulating film being sandwiched between the gate electrode and the wall surface;
a drain electrode electrically connected to the first layer; and
a source electrode electrically connected to the third layer in the mesa structure,
the nitride semiconductor structure having a high dislocation region and a low dislocation region arranged along a direction parallel to a principal surface of lamination of the nitride semiconductor structure, a dislocation density of the low dislocation region being lower than that of the high dislocation region,
the mesa structure being formed in the low dislocation region.

2. The nitride semiconductor device according to claim 1, further comprising:
a fourth layer formed on the wall surface in the second layer and having a different conductive characteristic from that of the second layer.

3. The nitride semiconductor device according to claim 1, further comprising:
a base layer supporting the nitride semiconductor structure, wherein
the base layer comprises an insulating film having an opening for exposing a part of a main surface of the base layer, and
the first layer is formed in a region extending from the opening to an upper area of the insulating film.

4. The nitride semiconductor device according to claim 3, wherein
the insulating film is made of oxide silicon, silicon nitride, or silicon oxynitride, or combinations thereof.

5. The nitride semiconductor device according to claim 1, further comprising:
a base layer supporting the nitride semiconductor structure, wherein
the base layer has a depression recessed from a main surface of the base layer, and
the first layer is formed on the main surface of the base layer including an interior of the depression.

6. The nitride semiconductor device according to claim 3, wherein
the base layer includes a sapphire substrate.

7. The nitride semiconductor device according to claim 3, wherein
the base layer comprises a conductive base layer being made of a conductive material, and
the drain electrode is formed on a surface of the conductive base layer on a side opposite from the first layer.

8. A manufacturing method for a nitride semiconductor device, comprising:
a structure formation step of forming a first layer made of an n-type Group III nitride semiconductor on a base layer, a second layer made of a p-type Group III nitride semiconductor on the first layer, and a third layer made of an n-type Group III nitride semiconductor on the second layer, to form a nitride semiconductor structure having a high dislocation region and a low dislocation region arranged along a direction parallel to a main surface of the base layer, a dislocation density of the low dislocation region being lower than that of the high dislocation region;
a mesa structure formation step of forming a wall surface extending from the first, second, to third layers to form a mesa structure having a lateral surface which forms the wall surface in the low dislocation region;
a gate insulating film formation step of forming a gate insulating film on the wall surface of the mesa structure to extend over the first, second, and third layers;
a gate electrode formation step of forming a gate electrode so as to face the wall surface in the second layer such that the gate insulating film is sandwiched between the gate electrode and the wall surface;
a drain electrode formation step of forming a drain electrode so as to be electrically connected to the first layer; and
a source electrode formation step of forming a source electrode so as to be electrically connected to the third layer in the mesa structure.

9. The manufacturing method for a nitride semiconductor device according to claim 8, further comprising:
a fourth layer formation step of forming a fourth layer having a different conductive characteristic from that of the second layer on a semiconductor surface portion of the second layer exposed by the forming of the wall surface in the mesa structure formation step.

10. The manufacturing method for a nitride semiconductor device according to claim 8, the structure formation step comprising;
an insulating film formation step of forming an insulating film on the main surface of the base layer, the insulating film having an opening for exposing a part of the main surface of the base layer, and
a step of forming the nitride semiconductor structure in a region extending from the opening to an upper area of the insulating film by growing a Group III nitride semiconductor from the opening using the insulating film as a mask.

11. The manufacturing method for a nitride semiconductor device according to claim 8, the structure formation step comprising:
a depression formation step of forming a depression on the main surface of the base layer by recessing the main surface of the base layer; and
a step of forming the nitride semiconductor structure on the main surface of the base layer by growing a Group III nitride semiconductor from the main surface of the base layer comprising a main surface of an interior of the depression.

12. The manufacturing method for a nitride semiconductor device according to claim 8, wherein
the base layer comprises a substrate, and a conductive base layer formed on the substrate, the conductive base layer being made of a conductive material, and
the drain electrode formation step comprises a step of removing the substrate, and a step of forming a drain electrode on a surface of the conductive base layer exposed by removing the substrate.
